(19) United States
(12) Patent Application Publication
(10) Pub. No.: US 2025/0293326 A1
(43) Pub. Date: Sep. 18, 2025

(54) METHOD AND SYSTEM FOR DETECTING BATTERY DEFECT IN FORMATION PROCESS

(71) Applicant: SK On Co., Ltd., Seoul (KR)

(72) Inventors: Young Bee KIM, Daejeon (KR); Sang Jo MOON, Daejeon (KR); Kyung Hee JEONG, Daejeon (KR); Yu Jin JEONG, Daejeon (KR); Hyun Seong CHOI, Daejeon (KR); Yu Jin LEE, Daejeon (KR)

(21) Appl. No.: 19/075,789

(22) Filed: Mar. 11, 2025

(30) Foreign Application Priority Data
Mar. 12, 2024 (KR) 10-2024-0034243
Feb. 25, 2025 (KR) 10-2025-0024349

(51) Int. Cl. H01M 10/48; G01R 31/3842; G01R 31/396; H01M 10/04; H01M 10/44; H02J 7/00

(52) U.S. Cl. CPC H01M 10/48; G01R 31/3842; G01R 31/396; H01M 10/0481; H01M 10/44; H02J 7/0047

(57) ABSTRACT

A method of detecting a battery defect in a formation process, the method includes pressurizing a battery cell in the formation process, charging the battery cell to raise a voltage of the battery cell to a target voltage during a first time period of a charging time period, and to maintain the target voltage of the battery cell during a second time period of the charging time period, in the formation process, measuring a current of the battery cell during the second time period or the voltage of the battery cell after the second time period, and detecting a defect in the battery cell, based on the current or voltage measured in the measuring. A pressurization time period of the pressurizing overlaps at least a portion of the charging time period.

### CROSS-REFERENCE TO RELATED APPLICATION(S)

This patent document claims the priority and benefits of Korean Patent Application Nos. 10-2024-0034243 and 10-2025-0024349 filed on Mar. 12, 2024 and Feb. 25, 2025, the disclosure of which is incorporated herein by reference in its entirety.

### TECHNICAL FIELD

The present disclosure relates to a method and system for detecting a battery defect in a formation process.

### BACKGROUND

In terms of batteries, secondary batteries, unlike primary batteries, are convenient in that the secondary batteries can be charged and discharged, and thus have drawn significant attention as a power source for various mobile devices and electric vehicles. An electrode assembly, formed by stacking a cathode plate, an anode plate, and a separator or winding the cathode plate, the anode plate, and the separator in the form of a roll, may be accommodated in a case of a battery cell. A plurality of battery cells may be stacked in a predetermined direction and accommodated in a battery module or a battery pack. The battery pack may include a plurality of battery modules.

Detecting battery defects in a battery manufacturing process may be crucial for ensuring battery safety, and the productivity of the manufacturing process may be enhanced as the efficiency of detecting a battery defect increases.

### SUMMARY

An aspect of the present disclosure provides a method and system for detecting a battery defect in a formation process. An aspect of the present disclosure may improve accuracy and reliability of detecting a defect in a battery cell. The improved accuracy and reliability of detecting a defect may mean that a period of time required to detect a defect is shortened (for example, a period of time required for defect detection is shortened to less than one day), which may be advantageous.

A battery may be used in eco-friendly electric vehicles, hybrid vehicles, or the like, to ameliorate the effects of climate change by suppressing air pollution and greenhouse gas emissions. Thus, according to an embodiment of the present disclosure, a method and system for detecting a battery defect in a formation process may contribute to eco-friendly construction (for example, improving a speed of eco-friendly construction and/or preventing environmental pollution due to a defect in a shipped battery).

According to an aspect of the present disclosure, there is provided a method of detecting a battery defect in a formation process, the method including pressurizing a battery cell in the formation process, charging the battery cell to raise a voltage of the battery cell to a target voltage during a first time period of a charging time period, and to maintain the target voltage of the battery cell during a second time period of the charging time period, in the formation process, measuring a current of the battery cell during the second time period or the voltage of the battery cell after the second time period, and detecting a defect in the battery cell, based on the current or voltage measured in the measuring. A pressurization time period of the pressurizing may overlap at least a portion of the charging time period.

For example, the detecting may include detecting a defect in the battery cell, based on a difference between a pattern of the current of the battery cell during the second time period and a first reference.

For example, the detecting may include generating information indicating that the battery cell has a defect, when a slope of the pattern of the current is gentler than a slope of the first reference or when a cumulative value of the pattern of the current is greater than a cumulative value of the first reference.

For example, the detecting may include generating information indicating that the battery cell has a first type of defect when the slope of the pattern of the current is steeper than a slope of a third reference or when the cumulative value of the pattern of the current is less than a cumulative value of the third reference, and generating information indicating that the battery cell has a second type of defect when the slope of the pattern of the current is gentler than the slope of the third reference or when the cumulative value of the pattern of the current is greater than the cumulative value of the third reference.

For example, the detecting may include detecting a defect in the battery cell, based on a difference between a pattern of the voltage of the battery cell and a second reference after the second time period. A time period after the second time period may include a rest time period of the battery cell.

For example, the detecting may include generating information indicating that the battery cell has a defect, when a slope of the pattern of the voltage is steeper than a slope of the second reference.

For example, the detecting may include generating information indicating that the battery cell has a first type of defect, when the slope of the pattern of the voltage is gentler than a slope of a fourth reference, and generating information indicating that the battery cell has a second type of defect, when the slope of the pattern of the voltage is steeper than the slope of the fourth reference.

For example, the charging may include charging the battery cell in a constant current mode during the first time period, and charging the battery cell in a constant voltage mode during the second time period.

For example, the pressurization time period may overlap the first time period, and overlaps the second time period.

For example, a pressurization pressure in the pressurizing may be greater than 0.1 MPa and less than 500 MPa.

For example, the method may further include formation charging or formation charging and discharging the battery cell after the measuring. The charging may correspond to press pre-charging (PPC) or pre-charging before the formation charging or formation charging and discharging.

For example, the method may further include performing at least one of aging for stabilizing the battery cell and degassing for removing gas in the battery cell, after the measuring.

According to another aspect of the present disclosure, there is provided a system of detecting a battery defect in a formation process, the system including a pressurizer configured to pressurize a battery cell which is to be subjected to the formation process, a charger configured to charge the battery cell in a constant current mode and to charge the battery cell in a constant voltage mode after the constant current mode, in the formation process, a measurer configured to measure a current of the battery cell during the constant voltage mode or a voltage of the battery cell after the constant voltage mode, and a controller configured to detect a defect in the battery cell, based on the current or voltage measured by the measurer. The pressurizer may be configured to pressurize the battery cell in at least one of the constant current mode and the constant voltage mode.

For example, the controller may be configured to detect a defect in the battery cell, based on a difference between a pattern of the current of the battery cell and a first reference during the constant voltage mode, or to detect a defect in the battery cell, based on a difference between a pattern of the voltage of the battery cell and a second reference after the constant voltage mode.

For example, the pressurizer may be configured to pressurize the battery cell at a pressure greater than 0.1 MPa and less than 500 MPa during the constant current mode, and to pressurize the battery cell at a pressure greater than 0.1 MPa and less than 500 MPa during the constant voltage mode.

### BRIEF DESCRIPTION OF DRAWINGS

Certain aspects, features, and advantages of the present disclosure are illustrated by the following detailed description with reference to the accompanying drawings.

FIG. 1 is a flowchart illustrating battery processes to which a formation process in a method and system for detecting a battery defect in a formation process belongs according to an embodiment of the present disclosure.

FIG. 2A is a flowchart illustrating a timing for detecting a defect in a formation process in a method and system for detecting a battery defect in a formation process according to an embodiment of the present disclosure.

FIG. 2B is a graph illustrating a voltage of a battery cell over time in a formation process in a method and system for detecting a battery defect in a formation process according to an embodiment of the present disclosure.

FIG. 3 is a diagram illustrating a system for detecting a battery defect in a formation process according to an embodiment of the present disclosure.

FIG. 4A is a flowchart illustrating a battery cell defect detected, based on a current (or a capacity), by a method and system for detecting a battery defect in a formation process according to an embodiment of the present disclosure.

FIG. 4B is a flowchart illustrating a battery cell defect detected, based on a voltage, by a method and system for detecting a battery defect in a formation process according to an embodiment of the present disclosure.

FIGS. 5A to 5C are graphs illustrating a pressurization time period in a method and a system for detecting a battery defect in a formation process according to an embodiment of the present disclosure, overlapping at least one of a first time period (a constant current mode), a second time period (a constant voltage mode), and a rest time period.

FIG. 6A is a graph illustrating the presence or absence of a battery cell defect or a type of battery cell defect detected, based on a current (or a capacity), by a method and system for detecting a battery defect in a formation process according to an embodiment of the present disclosure.

FIG. 6B is a graph illustrating the presence or absence of a battery cell defect or a type of battery cell defect detected, based on a voltage, by a method and system for detecting a battery defect in a formation process according to an embodiment of the present disclosure.

### DETAILED DESCRIPTION

Features of the present disclosure disclosed in this patent document are described by example embodiments with reference to the accompanying drawings.

The present disclosure can be implemented in some embodiments to provide a method and system for detecting a battery defect in a formation process.

Before describing embodiments of the present disclosure, the words and terminologies used in the specification and claims should not be construed with common or dictionary meanings, but construed as meanings and conception coinciding the spirit of the present disclosure under a principle that the inventor(s) may appropriately define the conception of the terminologies to explain the present disclosure in the optimum method.

The same reference numerals in the drawings refer to components or elements performing substantially the same function. For ease of description and understanding, the same reference numerals may be used in different embodiments.

As used herein, the singular forms “a,” “an,” and “the” are intended to include the plural forms as well, unless the context clearly indicates otherwise. As used herein, the term “and/or” includes any one and any combination of any two or more of the associated listed items. It will be further understood that the terms “comprises” and/or “comprising,” when used in this disclosure, specify the presence of stated features, integers, operations, operations, elements, components or a combination thereof, but do not preclude the presence or addition of one or more other features, integers, operations, operations, elements, components, and/or groups thereof.

In addition, the terms “upper side,” “upper portion,” lower side,” “lower portion,” “side surface,” “front surface,” “rear surface” and the like are described based on a direction illustrated the drawings, and may be described differently when a direction of a corresponding object is changed.

In addition, as used herein, terms including an ordinal number such as “first” and “second” may be used to distinguish between components. The ordinal number is used to distinguish the same or similar components from each other, and the meaning of the term should not be limitedly interpreted due to the use of the ordinal number. For example, components combined with the ordinal number should not be construed as limiting the order of use or arrangement by the number. If necessary, respective ordinal numbers may be used interchangeably.

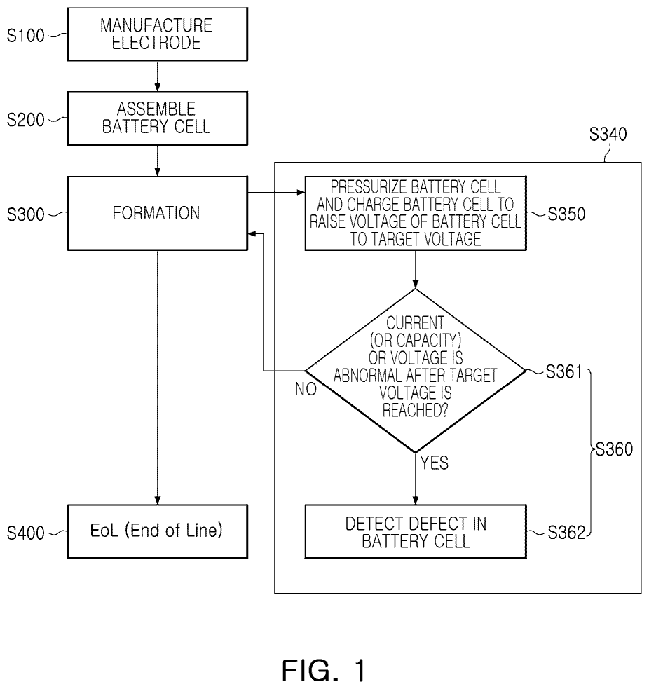

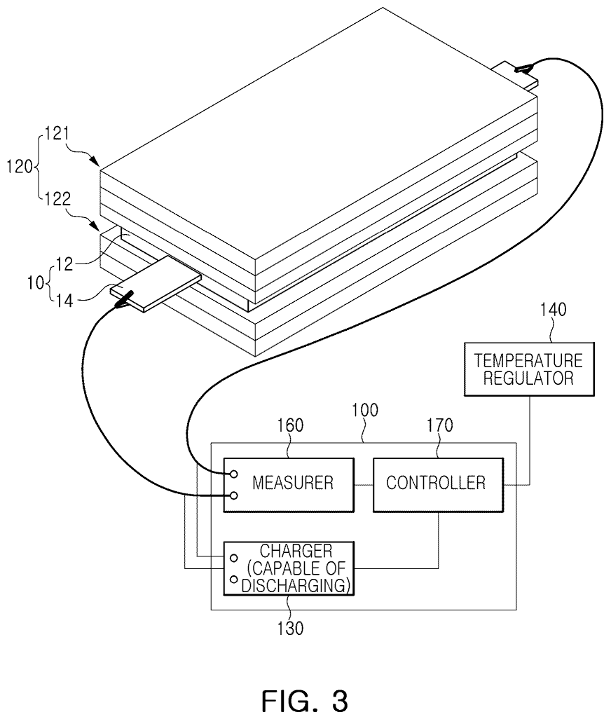

Referring to FIGS. 1 and 3, a formation process S300 of a method and system (100 in FIG. 3) for detecting a battery defect in a formation process according to an embodiment of the present disclosure may be one of sequentially performed battery processes (S100, S200, S300, and S400). The battery processes may include an electrode manufacturing process (S100), a battery cell assembly process (S200), a formation process (S300), and an EoL process (S400). An end of line (EoL) may be a post-battery process.

The electrode manufacturing process (S100) may include an operation of manufacturing battery electrodes (14 in FIG. 3) of at least one battery cell (10 in FIG. 3). For example, the electrode manufacturing process (S100) may include an operation of forming a slurry by mixing an active material, a conductive agent, a binder, and a solvent, an operation of coating the slurry on both surfaces of a cathode plate (for example, an aluminum plate, a copper plate), an operation of rolling the coated cathode plate, an operation of forming electrodes by slitting the coated and rolled cathode plate, an operation of vacuum-drying the electrodes, and an operation of manufacturing battery electrodes (14 in FIG. 3) by notching the dried electrodes.

Prior to the formation process (S300) and a measuring operation (S360), the battery cell assembly process (S200) may include an operation of coupling a battery case (12 in FIG. 3) and the battery electrodes (14 in FIG. 3) to each other and manufacturing a battery cell (10 in FIG. 3) by injecting an electrolyte into the battery case (12 in FIG. 3), and may be included in the method according to an embodiment of the present disclosure.

For example, the battery cell assembly process (S200) may include an operation of assembling tab-shaped battery electrodes 14 (for example, a porous polymer film or a porous non-woven fabric) using a specific method (for example, at least one of a winding method, a stacking method, a jelly-roll method, a Z-folding method, and a stack-folding method), an operation of welding tab-shaped battery electrodes (14 in FIG. 3) to connect a cathode to a cathode or an anode to an anode, an operation of arranging the welded battery electrodes (14 in FIG. 3) in the battery case (12 in FIG. 3), and an operation of injecting an electrolyte into the battery case (12 in FIG. 3). The battery case (12 in FIG. 3) may be a pouch-type case including a sealing portion, but may be implemented as a cylindrical case or a prismatic case depending on the design.

The formation process (S300) may include an operation of charging at least one battery cell (10 in FIG. 3) such that the at least one battery cell (10 in FIG. 3), assembled by the battery cell assembly process (S200), has electrical properties. In this case, a solid electrolyte interphase layer may be formed on anode surfaces of the battery electrodes (14 in FIG. 3), and thus the at least one battery cell (10 in FIG. 3) may have a microscopic structure capable of continuously undergoing electrochemical reactions depending on voltages of the battery electrodes (14 in FIG. 3).

For example, between the formation process (S300) and the EoL process (S400), a plurality of battery cells (10 in FIG. 3) may be stacked and assembled into a single battery module. For example, a plurality of battery modules may be assembled into a single battery pack or a single battery rack.

The EoL process (S400) may include an inspection operation for at least one battery cell having electrical properties, after the formation process (S300). For example, the inspection may include at least one of electrical performance (for example, capacity, charge/discharge voltage/current, internal resistance, or insulating resistance) inspection, temperature sensor performance inspection, battery management system (BMS) performance inspection, and battery cell exterior inspection of the at least one battery cell. A battery that has completed the EoL process (S400) may be shipped for use in eco-friendly vehicles such as electric vehicles or in energy storage systems.

For example, a quality defect in battery electrodes (14 in FIG. 3) manufactured by the electrode manufacturing process (S100), a welding defect in a battery cell manufactured by the battery cell assembly process (S200), or a facility defect in the electrode manufacturing process (S100) and the battery cell assembly process (S200) may cause a defect in a battery cell (10 in FIG. 3). For example, the defect in the battery cell (10 in FIG. 3) may include a low-voltage defect in which a voltage of the battery cell (10 in FIG. 3) is abnormally lowered, and may cause degradation in a lifespan and/or safety of the battery cell (10 in FIG. 3).

In general, in order to detect a defect in a battery cell (for example, a low-voltage defect), a voltage pattern of the battery cell, resulting from leaving the battery cell unattended for a long period (for example, several days) in a formation process, may be used. However, leaving the battery cell for such a long period (for example, several days) may act as a limitation in reducing a total required period of the formation process, and may cause a decrease in overall productivity of battery processes.

The method and system for detecting a defect in a battery cell (10 in FIG. 3) according to an embodiment of the present disclosure may include an operation (S340) of detecting a defect in the battery cell (10 in FIG. 3) in the formation process (S300), an operation (S350) of pressurizing the battery cell (10 in FIG. 3) and charging the battery cell (10 in FIG. 3) to raise a voltage of the battery cell 10 to a target voltage, and an operation (S362) of detecting a defect in the battery cell (10 in FIG. 3) depending on whether a current (or a capacity) or a voltage is abnormal (S361) after the target voltage is reached.

Referring to FIGS. 1, 2A, and 3, the method according to an embodiment of the present disclosure may include a pressurizing operation (S351), a charging operation (S352), a measuring operation (S353), and a detecting operation (S360). The system according to an embodiment of the present disclosure may include a pressurizer 120, a charger 130, a measurer 160, and a controller 170.

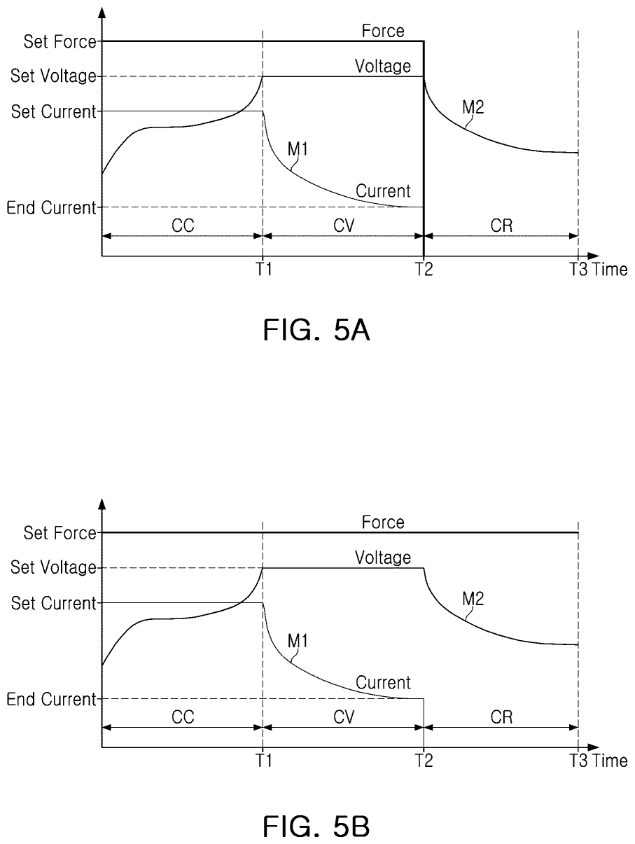

In the charging operation (S352), the charger 130 may charge (for example, charge in a constant current mode) a battery cell (10 in FIG. 3) to raise a voltage of the battery cell (10 in FIG. 3) to a target voltage (Set Voltage in FIGS. 5A to 5C) during a first time period (CC in FIGS. 5A to 5C) of a charging time period in the formation process (S300), and may charge (for example, charge in a constant voltage mode) the battery cell (10 in FIG. 3) to maintain the target voltage (Set Voltage in FIGS. 5A to 5C) of the battery cell (10 in FIG. 3) during a second time period (CV in FIGS. 5A to 5C) of the charging time period. The maintaining of the voltage may include fine fluctuating of the voltage and may include converging to the target voltage when effectively deviating from the target voltage.

Voltages of multiple battery cells before the charging operation (S352) may have a high variation therebetween, and thus the voltages before the charging operation (S352) may be difficult or inefficient to use for accurately detecting a defect. In the charging operation (S352), the charger 130 may equalize the multiple battery cells to the target voltage (Set Voltage in FIGS. 5A to 5C) during the first time period (CC in FIGS. 5A to 5C), thereby improving detection accuracy and reliability in the detecting operation (S360).

In the measuring operation (S353), the measurer 160 may measure a current M1 of the battery cell (10 in FIG. 3) during a second time period (CV in FIGS. 5A to 5C) or a voltage M2 of the battery cell (10 in FIG. 3) after a second time period (for example, CR in FIGS. 5A to 5C).

In the charging operation (S352), the charger 130 may charge the multiple battery cells while maintaining the voltages of the multiple battery cells during the second time period (CV in FIGS. 5A to 5C). Thus, a voltage variable may be excluded from the current M1 of the multiple battery cells during the second time period, and the current M1 of the multiple battery cells during the second time period may be efficient in improving defect detection accuracy and reliability.

In the charging operation (S352), the charger 130 may charge the multiple battery cells while maintaining the voltages of the multiple battery cells during the second time period (CV in FIGS. 5A to 5C). Thus, the multiple battery cells may equalize variables (for example, state of charge), other than the voltages, during the second time period, or may stabilize an initial condition when self-discharging is performed from the target voltage. Accordingly, the voltage M2 of the battery cell after the second time period (for example, CR in FIGS. 5A to 5C) may be efficient in improving defect detection accuracy and reliability.

In the detecting operation (S360), the controller 170 may detect a defect in the battery cell (10 in FIG. 3), based on the measured current M1 (including a capacity) or voltage M2. Each of the current M1 and the voltage M2 may be efficient in improving defect detection accuracy and reliability. In the detecting operation (S360), the controller 170 may improve accuracy and reliability of detecting a defect in the battery cell. Improving defect detection accuracy and reliability may mean that a period of time required to detect a defect is shortened (for example, a period of time required for defect detection is shortened to less than one day), which may be advantageous.

In addition, in the detecting operation (S360), the controller 170 may appropriately select one (both) of the current M1 and the voltage M2 depending on the design (for example, a formation process design/schedule, a battery cell design/model, or a type of defect to be detected, thereby flexibly detecting a defect in the battery cell depending on the circumstance, or further improving accuracy and reliability of detecting a defect in the battery cell using both the current M1 and the voltage M2.

In the pressurizing operation (S351), the pressurizer 120 may pressurize the battery cell (10 in FIG. 3). A pressurization time period (for example, corresponding to Force in FIGS. 5A to 5C) of the pressurizing operation (S351) of the pressurizer 120 may overlap at least a portion of a charging time period CC and/or a charging time period CV.

A variation may be present between internal states (for example, solid electrolyte interphase layer states or gaseous states) of a plurality of battery cells before pressure is applied, and the variation may be a variable, affecting defect detection accuracy and reliability at the current M1 and/or the voltage M2. Accordingly, the pressurizer 120 in the pressurizing operation (S351) may pressurize the plurality of battery cells for at least a partial period of time of the charging operation (S352), thereby removing the variation between the internal states of the plurality of battery cells and further improving accuracy and reliability of detecting a defect in the battery cell.

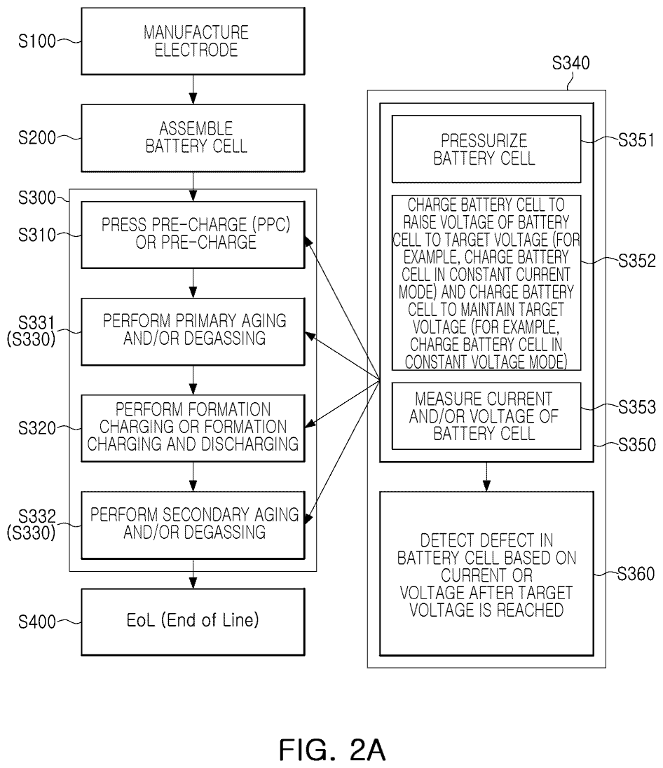

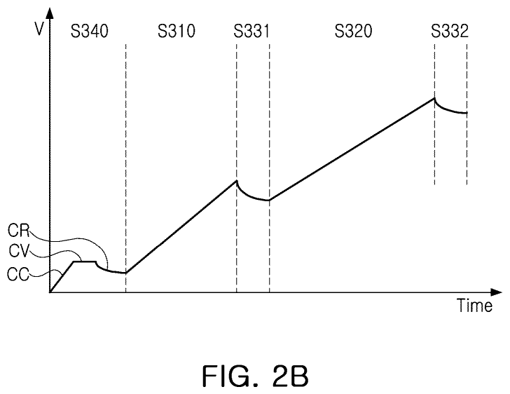

Referring to FIGS. 2A and 2B, the method according to an embodiment of the present disclosure may further include an operation (S320) of formation charging or formation charging and discharging the battery cell (10 in FIG. 3) after the measuring operation (S353), and may further include an operation of performing at least one of aging for stabilizing the battery cell (10 in FIG. 3) and degassing for removing gas (for example, gas generated due to the formation of electrical properties) in the battery cell (10 in FIG. 3), after the measuring operation (S353). The charging operation (S352) may correspond to a press pre-charging (PPC) operation or a pre-charging operation (S310).

However, the present disclosure is not limited to the pressurizing operation (S351), the charging operation (S352), the measuring operation (S353), and the detecting operation (S360) being performed before the operations (S320) and (S330). For example, the pressurizing operation (S351), the charging operation (S352), the measuring operation (S353), and the detecting operation (S360) may be performed during the operation (S320) and/or the operation (S330) depending on the design.

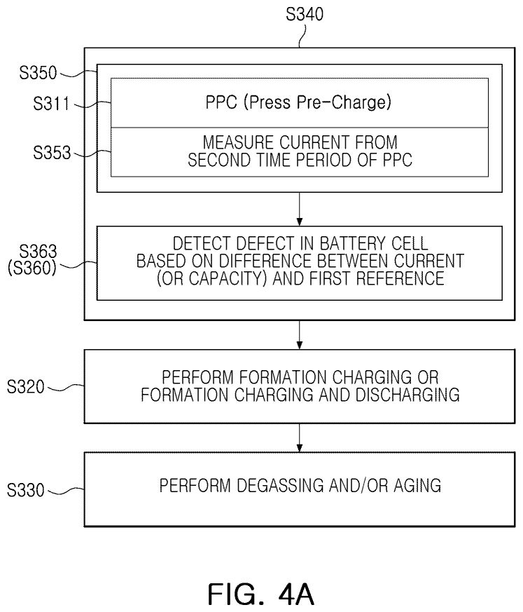

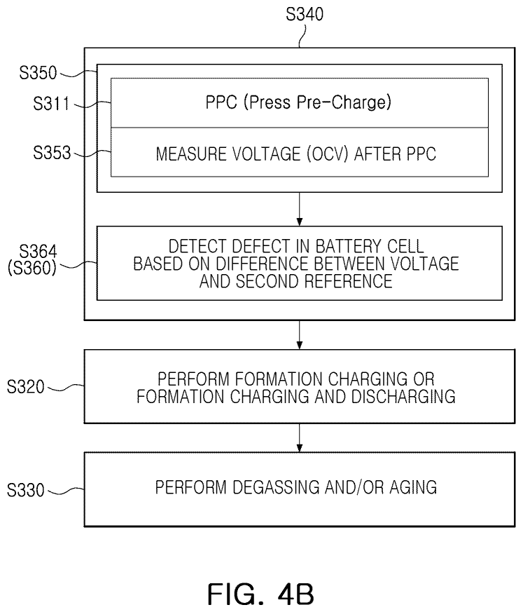

For example, when the operation (S310) is a PPC operation (S311 in FIGS. 4A and 4B), the PPC operation may correspond to a combination of the pressurizing operation (S351) and the charging operation (S352), and the pressurizer 120 may have a configuration (for example, a magnitude, a pressure, and a pressurization time period) optimized for the PPC operation. For example, when the operation (S310) is a pre-charging operation, the pre-charging operation may correspond to the charging operation (S352), and the pressurizer 120 may have a configuration (for example, a magnitude, a pressure, and a pressurization time period) optimized for defect detection.

For example, the operation (S310) may include initially charging the battery cell (10 in FIG. 3) with a predetermined capacity (for example, 20%) after the battery cell (10 in FIG. 3) is assembled. In this case, the inside of the battery cell (10 in FIG. 3) may be gradually cured. The operation (S320) may include charging the battery cell (10 in FIG. 3) beyond the predetermined capacity (for example, a voltage increase) (for example, 20%), and may further include discharging the battery cell (10 in FIG. 3) to the predetermined capacity (for example, 20%), depending on the design.

For example, the operation (S330) may include a primary aging and/or degassing operation (S331), and may include a secondary aging and/or degassing operation (S332). The operation (S320) may be performed between the operation (S331) and the operation (S332). Depending on a design, the operation (S320) and the operation (S332) may be alternately performed a plurality of times. For example, aging may include room-temperature aging, in which a battery cell is provided with a rest (no charging or discharging or a voltage drop) in a room-temperature range (for example, 20 to 35 degrees Celsius), and may include high-temperature aging, in which a battery cell is provided with a rest (no charging or discharging or a voltage drop) in a high-temperature range (for example, 35 degrees Celsius or higher).

Referring to FIGS. 2A, 3, and 5A to 5C, in the pressurizing operation (S351), the pressurizer 120 may be configured to pressurize the battery cell 10 on which the formation process is to be performed, and may pressurize the battery cell 10 during at least one of the constant current mode (corresponding to CC in FIGS. 5A to 5C) and the constant voltage mode (corresponding to CV in FIGS. 5A to 5C).

For example, the battery cell 10 may be formed by accommodating an electrode assembly including a cathode plate, an anode plate, and a separator in a casing, injecting an electrolyte into the casing, and then sealing the casing. In this case, electrodes 14, respectively connected to the cathode plate and the anode plate, may be exposed to the outside of the casing.

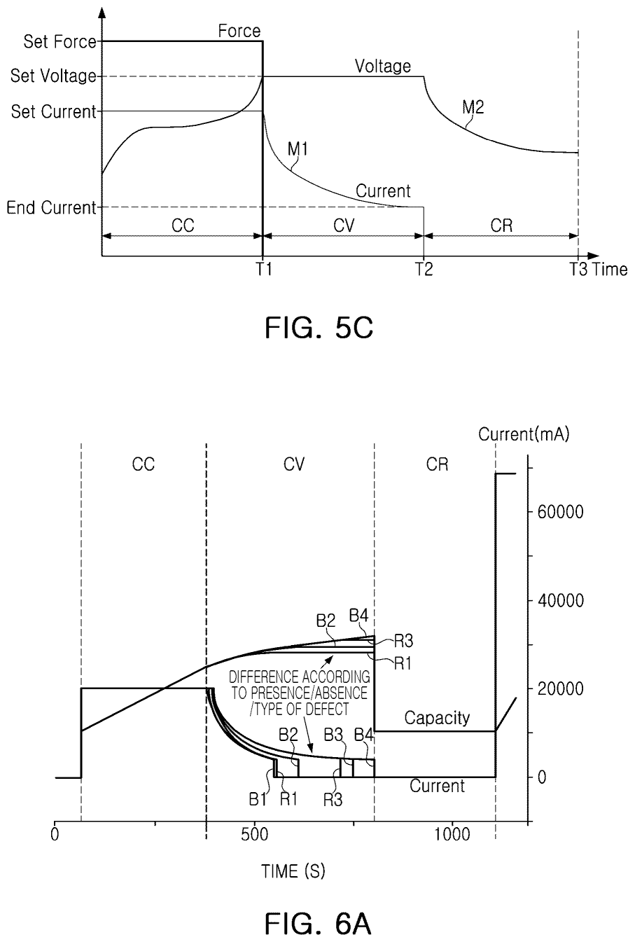

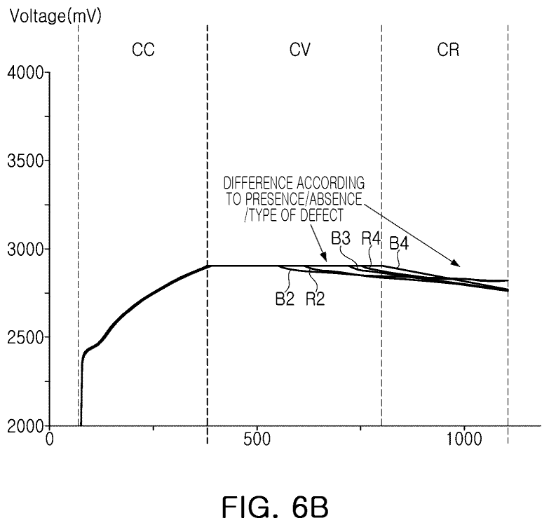

A model (type or category) of the battery cell 10 is not limited. For example, a shape (for example, pouch-type, prismatic, cylindrical) or a material (for example, lithium iron phosphate (LFP), LiNiMnCoO₂ (NCM), mid-Ni, or high-Ni) of the battery cell 10 is not limited. Depending on the model (type or category) of the battery cell 10, specific data of the graphs in FIGS. 6a and 6b may vary.

For example, the pressurizer 120 may include a plurality of support plates 121 and 122. The battery cell 10 may be disposed between the plurality of support plates 121 and 122. For example, each of the plurality of support plates 121 and 122 may be implemented as a polyhedron having a flat surface (an upper surface and/or a lower surface) opposing the battery cell 10, and the battery cell 10 may be compressed by a force applied in a vertical direction, which may be controlled by the controller 170. Depending on a design, the plurality of support plates 121 and 122 may be implemented to move only in the vertical direction while being prevented from moving in a horizontal direction by fastening means such as bolts and screws. Depending on the design, the pressurizer 120 may be implemented as a roller instead of the plurality of support plates 121 and 122, and the roller may compress the battery cell 10 by rolling on at least one of both surfaces of the battery cell 10.

For example, a pressurization pressure (Set Force in FIGS. 5A to 5C) at which the pressurizer 120 in the pressurizing operation (S351) pressurizes the battery cell 10 may be greater than 0.1 MPa and less than 500 MPa, but the present disclosure is not limited thereto. A range of the pressurization pressure may be similar to a pressurization pressure of the PPC operation, may be slightly greater than the pressurization pressure of the PPC operation to enhance defect detection accuracy and reliability, and may be non-destructively set so as not to degrade or damage the actual performance of the battery cell 10. A temperature before and after pressurization by the pressurizer 120 may be within a room-temperature range (for example, 20 to 35 degrees Celsius), and may decrease to −10 degrees Celsius or increase to 60 degrees Celsius depending on the design, but the present disclosure is not limited thereto.

Referring to FIGS. 5A and 5B, a pressurization time period (for example, corresponding to Force) may overlap the first time period CC, and may overlap the second time period CV. Referring to FIG. 5B, depending on the design, the pressurization time period (for example, corresponding to Force) may be further extended to a rest time period CR. Referring to FIG. 5C, depending on the design, the pressurization time period (for example, corresponding to Force) may overlap only one of the first time period CC and the second time period CV. FIGS. 5A to 5C illustrate that a pressurization pressure (Set Force) is constant, but the present disclosure not limited thereto.

In the charging operation (S352), the charger 130 may be configured to charge the battery cell 10 in the constant current mode (corresponding to CC in FIGS. 5A to 5C) in the formation process and to charge the battery cell 10 in the constant voltage mode (corresponding to CV in FIGS. 5A to 5C) after the constant current mode. Depending on the design, the charger 130 may further include an operation of formation charging or formation charging and discharging (S320 in FIG. 2A), and thus may be configured to perform charging and discharging. For example, the charger 130 may include a circuit converting commercial AC power to DC power, a circuit (for example, a regulation circuit, a feedback circuit) controlling a magnitude of current of DC power, a power supply such as a switched mode power supply (SMPS), and a circuit (for example, a triggering circuit) controlling whether a voltage (in the case of the constant voltage mode) and/or a current (in the case of the constant current mode) of DC power is output, and may be electrically connected to the electrode 14 through a wire (for example, a power cable), but the present disclosure is not limited thereto.

In the measuring operation (S353), the measurer 160 may be configured to measure a current of the battery cell 10 in the constant voltage mode (corresponding to CV in FIGS. 5A to 5C) or a voltage of the battery cell 10 after the constant voltage mode (corresponding to CR in FIGS. 5A to 5C). The measurer 160 may be configured to measure an open circuit voltage (OCV) of the battery cell 10. For example, the measurer 160 may be implemented as a digital multimeter, and may include an analog measurement circuit (for example, a sampling circuit, a buffer circuit, an amplification circuit, or an analog-to-digital conversion circuit). For example, the measurer 160 may include a sampling circuit, repeatedly sampling the voltage of the battery cell 10 every short cycle, an envelope detection circuit detecting the trend of the voltage of the battery cell 10 using frequency analysis (or Fourier transform-based analysis), and a timer (which may be included in the controller 170), generating a time value by counting time. For example, the measurer 160 may assign a time value to each of sampling voltages, determine whether the voltage of the battery cell rises or falls based on a difference between adjacent sampling voltages, and may also calculate a rise/fall rate (or a slope). Depending on the design, the measurer 160 may perform the determination and/or calculation only with a sampling voltage of a time value falling within a predetermined time period, among time values of the sampling voltage.

The controller 170 may be configured to detect a defect (for example, a low-voltage defect) of the battery cell 10, based on a difference between a voltage pattern measured by the measurer 160 and a reference pattern. For example, the controller 170 may be implemented as a data acquisition system, and may include a computing system (for example, a microcontroller, a programmable logic controller (PLC), an embedded system, and a manufacturing execution system (MES). For example, the computing system may include a processor (for example, a CPU or GPU), a memory (for example, a volatile memory or a nonvolatile memory), a recording medium, an input/output device, and a communication device. For example, the controller 170 may operate in a manner in which a processor executes one or more programs (and/or algorithms and logics) recorded in a memory or storage, and the above-described operation may correspond to instructions of a program, and may correspond to an operation performed by the method according to an embodiment of the present disclosure.

The temperature regulator 140 that may be included in the system (100 in FIG. 3) may regulate a temperature to fall within a temperature range (for example, a room-temperature range or a high-temperature range) set in the operation (S330 in FIG. 2A) of performing at least one of aging and degassing, and may be controlled by the controller 170. For example, the temperature regulator 140 may be implemented to control a structure of heating or cooling the inside of the chamber in which the battery cell 10 is accommodated. Depending on the design, at least a portion (for example, a temperature control logic or the like) of the temperature regulator 140 may be implemented as the controller 170.

Referring to FIGS. 4A and 6A, in the detecting operation (S363), the controller 170 (in FIG. 3) may detect a defect in the battery cell (10 in FIG. 3), based on a difference between a current pattern (Current in FIG. 6A) of the battery cell during the second time period CV and a first reference (R1 in FIG. 6A).

For example, in the second time period CV, a current pattern of a battery cell B1 and a first reference R1 may have a relatively small overall difference (for example, a slope, an average value, a value of a specific time, a period of time required to a specific value, an inflection point position, or the like) therebetween, and thus the controller may analyze the difference (value calculation, value comparison, or the like) to generate information indicating that the battery cell B1 has a defect. Conversely, in the second time period CV, a current pattern of each of battery cells B2, B3, and B4 and the first reference R1 may have a relatively large overall difference (for example, a slope, an average value, a value of a specific time, a period of time required to a specific value, an inflection point position, or the like) therebetween, and thus the controller may analyze the difference (value calculation, value comparison, or the like) to generate information indicating that the battery cells B2, B3, and B4 have a defect.

For example, when a pinhole is formed in a battery cell or metallic foreign matter infiltrates, a magnitude of a micro-short circuit in the battery cell may increase. The pinhole and the metallic foreign matter may correspond to defects in the battery cell. However, the defects are not limited to the pinhole and the metallic foreign matter. The battery cell may be charged (for example, charged in the constant voltage mode) to maintain a target voltage during the second time period CV. Accordingly, as the magnitude of the internal micro-short circuit increases, a current (and/or a charging capacity) during the second time period CV may also increase.

In the detecting operation (S363), the controller (170 in FIG. 3) may generate information indicating that the battery cell (10 in FIG. 3) has a defect when a slope of the current pattern (Current in FIG. 6A) is gentler than a slope of the first reference R1 or when a cumulative value (Capacity in FIG. 6A) of the current pattern is greater than a cumulative value (Capacity in FIG. 6A) of the first reference R1.

For example, in the second time period CV, a slope of a current pattern of the battery cell B1 may be slightly steeper than a slope of the first reference R1, and a cumulative value of a current of the battery cell B1 may be substantially equal to a cumulative value of the first reference R1, and thus the controller may analyze the slopes and/or the cumulative values to generate information indicating that the battery cell B1 has no defect. Conversely, in the second time period CV, a slope of a current pattern of each of the battery cells B2, B3, and B4 may be gentler than the slope of the first reference R1, and a cumulative value of a current of each of the battery cells B2, B3, and B4 may be greater than the cumulative value of the first reference R1, and thus the controller may analyze the slopes and/or the cumulative values to generate information indicating that the battery cells B2, B3, and B4 have a defect.

In the detecting operation (S363), the controller (170 in FIG. 3) may generate information indicating that the battery cell (10 in FIG. 3) has a first type of defect (for example, a pinhole defect) when the slope of the current pattern (Current in FIG. 6A) is steeper than a slope of a third reference R3 or when the cumulative value (Capacity in FIG. 6A) of the current pattern is less than a cumulative value of the third reference R3, and may generate information indicating that the battery cell (10 in FIG. 3) has a second type of defect (a metallic foreign matter defect) when the slope of the current pattern (Current in FIG. 6A) is gentler than the slope of the third reference R3 or when the cumulative value (Capacity in FIG. 6A) of the current pattern is greater than the cumulative value of the third reference R3.

For example, in the second time period CV, a slope of a current pattern of the battery cell B2 may be steeper than the slope of the third reference R3, and a cumulative value of a current of the battery cell B2 may be less than the cumulative value of the third reference R3, and thus, the controller may analyze the slopes and/or the cumulative values to generate information indicating that the battery cell B2 has a first type of defect (for example, a pinhole defect). Conversely, in the second time period CV, a slope of a current pattern of each of the battery cells B3 and B4 may be gentler than the slope of the third reference R3, and a cumulative value of a current of the battery cell B4 may be greater than the cumulative value of the third reference R3, and thus, the controller may analyze the slopes and/or the cumulative values to generate information indicating that the battery cells B3 and B4 have a second type of defect (for example, a metallic foreign matter defect).

For example, when a metallic foreign matter infiltrates into a battery cell, a magnitude of a micro-short circuit in the battery cell may further increase, as compared to a case in which a pinhole is formed in the battery cell. The pinhole and the metallic foreign matter may correspond to the first and second types of defects of the battery cell, but the present disclosure is not limited thereto.

Referring to FIGS. 4B and 6B, in the detecting operation (S364), the controller 170 (in FIG. 3) may detect a defect in the battery cell (10 in FIG. 3), based on a difference between a voltage pattern (Voltage in FIG. 6B) of the battery cell (10 in FIG. 3) and a second reference R2, after the second time period. A time period after the second time period may include a rest time period CR of the battery cell (10 in FIG. 3).

For example, in the rest time period CR, a voltage pattern of the battery cell B2 and the second reference R2 may have a relatively small overall difference (for example, a slope, an average value, a value of a specific time, an inflection point position, or the like) therebetween, and thus the controller may analyze the difference (value calculation, value comparison, or the like) to generate information indicating that the battery cell B2 has no defect. Conversely, in the rest time period CR, a voltage pattern of each of the battery cells B3 and B4 and the second reference R2 may have a relatively large overall difference (for example, a slope, an average value, a value of a specific time, an inflection point position, or the like) therebetween, and thus the controller may analyze the difference (value calculation, value comparison, or the like) to generate information indicating that the battery cells B3 and B4 have a defect.

For example, when a pinhole is formed in a battery cell or metallic foreign matter infiltrates, a magnitude of a micro-short circuit in the battery cell may increase. The pinhole and the metallic foreign matter may correspond to defects in the battery cell. However, the defects are not limited to the pinhole and the metallic foreign matter. The battery cell may not be charged and discharged during the rest time period CR. Thus, as the magnitude of the micro-short circuit increases, a self-discharge rate during the rest time period CR may further increase, and a voltage pattern may have a steeper slope.

In the detecting operation (S364), the controller (170 in FIG. 3) may generate information indicating that the battery cell (10 in FIG. 3) has a defect when a slope of the voltage pattern (Voltage in FIG. 6B) is steeper than a slope of the second reference R2.

For example, in the rest time period CR, a slope of the voltage pattern of the battery cell B2 may be gentler than the slope of the second reference R2, and thus the controller may analyze the slopes to generate information indicating that the battery cell B2 has no defect. Conversely, in the rest time period CR, a slope of the voltage pattern of each of the battery cells B3 and B4 is steeper than the slope of the second reference R2, the controller may analyze the slopes to generate information indicating that the battery cells B3 and B4 have a defect.

In the detecting operation (S364), the controller (170 in FIG. 3) may generate information indicating that the battery cell (10 in FIG. 3) has a first type of defect (for example, a pinhole defect) when the slope of the voltage pattern (Voltage in FIG. 6B) is gentler than a slope of a fourth reference R4, and may generate information indicating that the battery cell (10 in FIG. 3) has a second type of defect (for example, a metallic foreign matter defect) when the slope of the voltage pattern (Voltage in FIG. 6B) is steeper than the slope of the fourth reference R4. The pinhole and the metallic foreign matter may correspond to the first and second types of defects of the battery cell, but the present disclosure is not limited thereto.

For example, in the rest time period CR, a slope of a voltage pattern of the battery cell B3 may be gentler than the slope of the fourth reference R4, and thus the controller may analyze the slopes to generate information indicating that the battery cell B3 has a first type of defect (for example, a pinhole defect). Conversely, in the rest time period CR, the slope of the voltage pattern of the battery cell B4 may be steeper than the slope of the fourth reference R4, and thus the controller may analyze the slopes to generate information indicating that the battery cell B4 has a second type of defect (for example, a metallic foreign matter defect).

According to embodiments of the present disclosure, a method and system for detecting a battery defect in a formation process may improve accuracy and reliability of detecting a defect in a battery cell. The improved accuracy and reliability of detecting a defect may mean that a period of time required to detect a defect is shortened (for example, a period of time for defect detection is shortened to less than one day), which may be advantageous.

For example, the method and system may appropriately select one (or both) of a current (and/or a capacity) and a voltage of a battery cell depending on the design (for example, a formation process design/schedule, a battery cell design/model, or a type of defect to be detected), thereby flexibly detecting a defect in the battery cell depending on the circumstance, or further improving accuracy and reliability of detecting a defect in the battery cell using both the current and the voltage.

Only specific examples of implementations of certain embodiments are described. Variations, improvements and enhancements of the disclosed embodiments and other embodiments may be made based on the disclosure of this patent document.

What is claimed is:

1. A method of detecting a battery defect in a formation process, the method comprising:
pressurizing a battery cell in the formation process;
charging the battery cell to raise a voltage of the battery cell to a target voltage during a first time period of a charging time period, and to maintain the target voltage of the battery cell during a second time period of the charging time period, in the formation process;
measuring a current of the battery cell during the second time period or the voltage of the battery cell after the second time period; and
detecting a defect in the battery cell, based on the current or voltage measured in the measuring,
wherein a pressurization time period of the pressurizing overlaps at least a portion of the charging time period.

2. The method of claim 1, wherein the detecting includes detecting a defect in the battery cell, based on a difference between a pattern of the current of the battery cell during the second time period and a first reference.

3. The method of claim 2, wherein the detecting includes generating information indicating that the battery cell has a defect, when a slope of the pattern of the current is gentler than a slope of the first reference or when a cumulative value of the pattern of the current is greater than a cumulative value of the first reference.

4. The method of claim 3, wherein the detecting includes:
generating information indicating that the battery cell has a first type of defect when the slope of the pattern of the current is steeper than a slope of a third reference or when the cumulative value of the pattern of the current is less than a cumulative value of the third reference; and
generating information indicating that the battery cell has a second type of defect when the slope of the pattern of the current is gentler than the slope of the third reference or when the cumulative value of the pattern of the current is greater than the cumulative value of the third reference.

5. The method of claim 1, wherein
the detecting includes detecting a defect in the battery cell, based on a difference between a pattern of the voltage of the battery cell and a second reference after the second time period,
a time period after the second time period includes a rest time period of the battery cell.

6. The method of claim 5, wherein the detecting includes generating information indicating that the battery cell has a defect, when a slope of the pattern of the voltage is steeper than a slope of the second reference.

7. The method of claim 6, wherein the detecting includes:
generating information indicating that the battery cell has a first type of defect, when the slope of the pattern of the voltage is gentler than a slope of a fourth reference; and
generating information indicating that the battery cell has a second type of defect, when the slope of the pattern of the voltage is steeper than the slope of the fourth reference.

8. The method of claim 1, wherein the charging includes charging the battery cell in a constant current mode during the first time period, and charging the battery cell in a constant voltage mode during the second time period.

9. The method of claim 1, wherein the pressurization time period overlaps the first time period, and overlaps the second time period.

10. The method of claim 1, wherein a pressurization pressure in the pressurizing is greater than 0.1 MPa and less than 500 MPa.

11. The method of claim 1, further comprising:
formation charging or formation charging and discharging the battery cell after the measuring,
wherein the charging corresponds to press pre-charging (PPC) or pre-charging before the formation charging or formation charging and discharging.

12. The method of claim 1, further comprising:
performing at least one of aging for stabilizing the battery cell and degassing for removing gas in the battery cell, after the measuring.

13. A system of detecting a battery defect in a formation process, the system comprising:
a pressurizer configured to pressurize a battery cell which is to be subjected to the formation process;
a charger configured to charge the battery cell in a constant current mode and to charge the battery cell in a constant voltage mode after the constant current mode, in the formation process;
a measurer configured to measure a current of the battery cell during the constant voltage mode or a voltage of the battery cell after the constant voltage mode; and
a controller configured to detect a defect in the battery cell, based on the current or voltage measured by the measurer,
wherein the pressurizer is configured to pressurize the battery cell in at least one of the constant current mode and the constant voltage mode.

14. The system of claim 13, wherein the controller is configured to detect a defect in the battery cell, based on a difference between a pattern of the current of the battery cell and a first reference during the constant voltage mode, or to detect a defect in the battery cell, based on a difference between a pattern of the voltage of the battery cell and a second reference after the constant voltage mode.

15. The system of claim 13, wherein the pressurizer is configured to pressurize the battery cell at a pressure greater than 0.1 MPa and less than 500 MPa during the constant current mode, and to pressurize the battery cell at a pressure greater than 0.1 MPa and less than 500 MPa during the constant voltage mode.
